(19) United States
(12) Patent Application Publication
(10) Pub. No.: US 2020/0132779 A1
(43) Pub. Date: Apr. 30, 2020

(54) METHODS, SYSTEMS, AND DEVICES FOR PROVIDING DYNAMIC DATA ANALYTICS WITHIN BATTERY CHARGING SYSTEMS

(71) Applicant: EnerSys Delaware Inc., Reading, PA (US)

(72) Inventors: Mohammed Kechmir, Wyomissing, PA (US); Tony Reeves, Macungie, PA (US); Rui Zhou, Niskayuna, NY (US); David Letombe, Lille (FR)

(21) Appl. No.: 16/662,294

(22) Filed: Oct. 24, 2019

Related U.S. Application Data
(60) Provisional application No. 62/750,419, filed on Oct. 25, 2018.

(51) Int. Cl. G01R 31/385; G01R 31/371; G01R 31/382

(52) U.S. Cl. CPC G01R 31/385; G01R 31/382; G01R 31/371

(57) ABSTRACT

Methods, systems, and devices that include improvements to determining properties of a battery are described. For example, a method may include measuring one or more properties of a battery by a device communicatively coupled to the battery; transmitting the measured one or more properties to a computing device located remotely from the battery; detecting, by the computing device and based on the measured one or more properties, one or more anomalous conditions within the battery; and transmitting, by the computing device, an indication of the one or more anomalous conditions.

### CROSS-REFERENCE TO RELATED APPLICATION

The present application claims priority under 35 U.S.C. § 119 to U.S. Provisional Application No. 62/750,419, filed on Oct. 25, 2018, with the United States Patent and Trademark Office, the entire contents of which are incorporated by reference herein for all purposes.

### TECHNICAL FIELD

The present disclosure relates to batteries, and in particular, to methods, systems, and devices for providing dynamic data analytics within battery charging systems.

### BACKGROUND

Batteries have become increasingly important, with a variety of industrial, commercial, and consumer applications. Of particular interest are power applications involving “deep discharge” duty cycles, such as motive power applications. The term “deep discharge” refers to the extent to which a battery is discharged during service before being recharged. By way of counter-example, a shallow discharge application is one such as starting an automobile engine wherein the extent of discharge for each use is relatively small compared to the total battery capacity. Moreover, the discharge in such shallow discharge cases is followed soon after by recharging. Over a large number of repeated cycles very little of the battery capacity is used prior to recharging.

Conversely, deep discharge duty cycles are characterized by drawing a substantial majority of the battery capacity before the battery is recharged. Some motive power applications that require deep cycle capability include Class 1 electric rider trucks, Class 2 electric narrow aisle trucks and Class 3 electric hand trucks. Desirably, batteries installed in these types of vehicles must deliver a number of discharges during a year that may number in the hundreds. The cycle life of batteries used in these applications typically can range from 500-2000 total cycles so that the battery lasts a number of years before it needs to be replaced.

Interest and research in batteries has resulted in a variety of battery chemistries, with differing benefits and drawbacks. For example, “flooded” lead-acid batteries tend to be more economical, but may require periodic maintenance that includes replenishment of an electrolyte, which can spill; such batteries may also have reduced capacity over time resulting from liberation of acid during charging. Alternative lead-acid batteries may use a gelled electrolyte, which cannot spill and avoid the acid liberation problem, but have their own drawbacks in that the internal resistance may be higher, limiting the ability of such batteries to deliver high currents. Still other types of batteries include lithium-ion or lithium ion polymer batteries, nickel-cadmium, nickel-metal hydride, and others. The benefits and drawbacks of such battery types are known to those in the art and need not be discussed here. Regardless of the type of battery used in an application, two important properties of a given battery at a given point in time during usage is how much operating time is left before a charge is required, as well as how much charging time is needed for a “full” battery.

Field deployments of batteries in applications also take on many different forms. For example, some applications or industries utilize removable batteries, in which depleted batteries can be removed and swapped out with batteries having a greater stored charge. Such applications may use a number of batteries that is greater than the number of battery-powered devices or vehicles. Careful attention must be paid to ensure that enough batteries are in circulation to avoid disruptions or delays in performing tasks that utilize batteries or battery-powered devices. Attention must also be paid to the charge level of each battery, the discharge rate of each battery, and other battery characteristics, to ensure that the battery “network” is able to adequately support the operation utilizing the batteries.

### SUMMARY

The present disclosure also recognizes that there is growing interest in cloud-based monitoring of field operations via the collection, management, and analysis of data received from sensor-enabled devices deployed in the field. For example, rather than perform a rough “guess” as to the state of a particular battery in a particular warehouse, data may be collected and wirelessly transmitted from the battery to a server, which may perform analysis on the battery and provide results from such analysis to one or more users. Thus, a more accurate and battery-specific estimate as to the state of charge of the battery (or of the cells of a multi-cell battery) may be provided.

Aspects of the present disclosure provide a method comprising measuring one or more properties of a battery by a device communicatively coupled to the battery; transmitting the measured one or more properties to a computing device located remotely from the battery; detecting, by the computing device and based on the measured one or more properties, one or more anomalous conditions within the battery; and transmitting, by the computing device, an indication of the one or more anomalous conditions. Devices and apparatuses that implement the method are also provided.

The present disclosure also provides a battery monitoring system, comprising: a battery; a battery monitoring apparatus communicatively coupled to the battery; and a computing device communicatively coupled to the battery monitoring apparatus. The computing device is configured to perform operations comprising: receiving one or more measurements of characteristics of the battery; determining one or more anomalous properties of the battery; and transmitting one or more updates to a charger configured to charge the battery, wherein the one or more updates are configured to change an operation of the charger during charging of the battery to address the one or more anomalous properties of the battery.

### BRIEF DESCRIPTION OF THE DRAWINGS

The accompanying drawings, which are incorporated in and constitute a part of the specification, illustrate embodiments of the inventive concepts and, together with the description, serve to explain principles of the inventive concepts.

FIG. 1 is a schematic block diagram illustrating an example battery monitoring system according to some embodiments of the present inventive concepts.

FIG. 2 is a schematic block diagram illustrating an example battery monitoring system according to some embodiments of the present inventive concepts.

FIGS. 3-5 are flowcharts of example battery monitoring methods according to some embodiments of the present inventive concepts.

FIGS. 6 and 7A-B are illustrations of aspects of an example battery monitoring system according to some embodiments of the present inventive concepts.

FIGS. 8 and 9 are illustrations of aspects of an example battery monitoring system according to some embodiments of the present inventive concepts.

FIG. 10 is a schematic block diagram illustrating components of a computing device that may be used to implement one or more components within an example battery monitoring system according to some embodiments of the present inventive concepts.

### DETAILED DESCRIPTION

The present disclosure provides cloud-based monitoring of field operations, and particularly batteries deployed in the field, and provides the cloud-based monitoring via the collection, management, and analysis of data received from sensor-enabled devices deployed at a field site. Moreover, the present disclosure provides cloud-based control of the batteries deployed at the field site, for example by transmitting data or instructions to the field site to alter how the batteries are charged and/or discharged. Thus, not only does the present disclosure provide a more accurate estimate as to the state of charge of a particular battery at a given point in time, the present disclosure may include operations and methods that prolong a serviceable life of the particular battery.

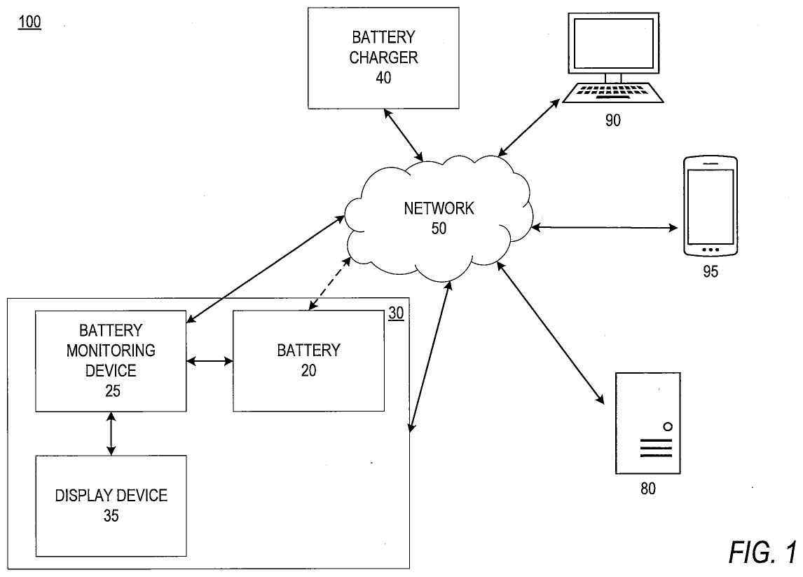

FIG. 1 illustrates an example battery monitoring system 100 in which a battery 20 is monitored by one or more components, including for example a battery monitoring device 25.

The phrase “battery monitoring” as used herein may include measuring values of properties of a battery at a point in time and/or over a period of time. “Battery monitoring” may also include estimating values of battery properties at past and/or present points in time, relative to a time when the estimation is performed. For example, a battery property may be estimated where the battery property is difficult, time-consuming, or energy-consuming to measure directly. In some aspects, and for some battery properties, first and second values measured at first and second points in time, respectively, may be used to estimate a third value at a third point in time occurring in between the first and second points in time (e.g., interpolation), or may be used to estimate a third value at a third point in time occurring after the later of the first and second points in time (e.g., extrapolation).

Thus, as used herein, “battery monitoring” may also include predicting future values of battery properties at a point in time in the future relative to when the prediction is made. Such predicted future values may be based on one or more measured and/or estimated values of properties of the battery, at points in time at and/or before when the prediction is made.

Example properties that may be measured, estimated, and/or predicted may include current (e.g., current flowing to the battery, current flowing from the battery), voltage (e.g., open-circuit voltage, voltage applied to load), battery temperature, battery state of charge, time remaining to charge, time remaining to discharge, and so on. Measured, estimated, and/or predicted battery properties may be based on other measured, estimated, and/or predicted properties of the battery. Other data or information available within the battery monitoring system 100 may also be used to measure, estimate, and/or predict battery properties, such as models of complex battery properties, stored history of battery usage data, and so on.

The battery 20 may be of any type compatible with the present disclosure, with examples including lead-acid batteries, lithium-ion batteries, and so on. The battery 20 may have one or more local sensors (not shown in FIG. 1) to detect one or more characteristics or properties of the battery 20, such as current, voltage, and/or temperature. For example, a current sensor may be used to sense current flowing to the battery 20 and/or current flowing from the battery 20; a voltage sensor may be used to sense a voltage of the battery 20 (such as under load or open-circuit); and/or a thermal sensor may be used to sense a temperature of the battery 20. Such sensors may be integrated into the battery 20 or present within the battery monitoring system 100 at location(s) relatively proximate to the battery 20. In some aspects herein, the battery 20 may be referred to as a battery asset 20.

In some embodiments, the sensors may be within the battery monitoring device 25. The battery monitoring device 25 may be electrically and/or communicatively coupled to the battery 20 and configured to receive measurements from the sensors of the battery 20 and/or the sensors of the battery monitoring device 25 and communicate the measurements to one or more recipients. The battery monitoring device 25 may include a transceiver that is configured to provide received measurements from the sensors of the battery 20 and/or the sensors of the battery monitoring device 25 to one or more remote devices (e.g., computing devices 90, 95, and/or a database server 80) via a network 50 to be described in more detail below. In some embodiments, the battery monitoring device 25 may include a processor configured to perform one or more calculations, estimations, predictions, analyses, or the like on the received measurements, and provide the results of the one or more calculations, estimations, predictions, analyses, or the like to the one or more remote devices via the network 50.

As illustrated in FIG. 1, the battery 20 may be used by a vehicle 30 in operation thereof. The battery monitoring device 25 may be located relatively proximate to the battery 20 (e.g., within the vehicle 30) or may be relatively remote from the battery (e.g., not within the vehicle 30). In some embodiments, the battery 20 may be detachable or disconnectable from the vehicle 30.

The battery 20 may be configured to be temporarily attachable to a charger 40 for charging thereof. The charger 40 may be configured to provide a charging current to batteries of one or more types. In addition, the battery charger 40 may be configured with one or more sensors (not shown in FIG. 1) to detect one or more characteristics or properties of a battery 20 being charged by the charger 40 and/or a battery 20 attached to the charger 40, regardless of whether the battery 20 is being charged. In other words, properties may be sensed from the battery 20 while the battery charger 40 is idle. Such properties, as discussed above, may include current, voltage, and/or temperature. For example, a current sensor may be used to sense current flowing to the battery 20 and/or current flowing from the battery 20; a voltage sensor may be used to sense a voltage of the battery 20 (such as under load or open-circuit); and/or a thermal sensor may be used to sense a temperature of the battery 20.

The battery monitoring device 40 may include a transceiver that is configured to provide received measurements from the sensors of the charger 40 to one or more remote devices (e.g., computing devices 90, 95, and/or a database server 80) via a network 50 to be described in more detail below. In some embodiments, the charger 40 may include a processor configured to perform one or more calculations, estimations, predictions, analyses, or the like on the received measurements, and provide the results of the one or more calculations, estimations, predictions, analyses, or the like to the one or more remote devices via the network 50.

Collected data from the battery 20 and/or the charger 40 may be communicated to one or more recipients. Estimations and/or predictions of battery properties based on the measurements may also be communicated. Examples of recipients may include a user of the vehicle 30 in which the battery 20 is installed or to be installed. Data may be communicated (e.g., graphically, tabularly, and/or numerically) to the user of the vehicle 30 via an user interface, such as a display device 35 mounted in a dashboard of the vehicle 30 or otherwise visible to the user during operation of the vehicle 30. Another example of a recipient is a user awaiting completion of charging of the battery 20 by the charger 40. Data may be communicated (e.g., graphically, tabularly, and/or numerically) to the user of the charger 40 via a user interface, such as a display device (none shown) present at the charger 40.

Other examples of recipients may be computing devices 90 and 95, which may communicate with the battery monitoring device 25 and/or charger 40 over a network 50, and which may be smartphones, tablets, desktop computers, laptop computers, thin clients, mainframes, servers, and so on. The computing devices 90 and 95 may be running software configured to receive the data and/or other values from the battery 20, the charger 40, and/or the battery monitoring device 25, and may perform one or more actions based thereon. As an example of such actions, the computing device 90 may be configured to receive data and/or other values from the battery 20 and/or the battery monitoring device 25, determine an appropriate notification (e.g., a notification of a state-of-charge of the battery 20, a notification of a remaining run time of the battery 20) that should be sent to the computing device 95, and cause transmission of the notification to the computing device 95, for example via the network 50.

In some embodiments, the battery monitoring device 25 may be integrated with the battery 20. In some embodiments, the battery monitoring device 25 may be integrated with the vehicle 30 and/or the charger 40.

In some embodiments, sensed values of properties, estimations of values of properties, and/or predictions of values of properties may be stored in a database at database server 80. The database server 80 may be a part of any of the computing devices 90, 95 of FIG. 1, or may be a part of the battery monitoring device 25, and/or may be a separate device as illustrated in FIG. 1. The database server 80, or other device storing sensed, estimated, or predicted values of properties may execute one or more programmatic instructions to organize and/or manage the stored values and may provide data responsive to queries received thereby. Such queries may be received, e.g., as commands in a structured or unstructured query language, and/or via an application programming interface (API), a web service, or the like.

In some embodiments, functionality described herein as being performed by the battery monitoring device 25 may be performed additionally or alternatively by one or more of the computing devices 90, 95 in the battery monitoring system 100 of FIG. 1. For example, proximate to the battery 20 may be sensors, which may sense properties of the battery 20 and communicate the sensed properties over the network 50 to one or more of the computing devices 90, 95, as indicated by the dashed arrow between the battery 20 and the network 50. The computing devices 90, 95 may analyze the communicated sensed properties and perform one or more estimations and/or predictions. In some embodiments, all or part of the battery monitoring device 25 may overlap with one or more of the devices of the battery monitoring system 100 of FIG. 1, including the computing devices 90, 95 or the database server 80.

The computing devices 90, 95 may include a display device for displaying measurements, estimations, and/or predictions (e.g., graphically, tabularly, and/or numerically). In some embodiments, the battery 20, the battery monitoring device 25, the charger 40, and/or the computing devices 90, 95 may include input devices configured to accept user input, such as an initial state of charge of the battery 20, desired type of output/display, user settings (e.g., temperature values provided in Celsius or Fahrenheit) and so on.

The network 50 may include a local network, a wireless, coaxial, fiber, or hybrid fiber/coaxial distribution system, a Wi-Fi or Bluetooth network, or any other desired network. The network 50 may be made up of one or more subnetworks, each of which may include interconnected communication links of various types, such as coaxial cables, optical fibers, wireless links, and the like. The network 50 and/or the subnetworks thereof may include, for example, networks of Internet devices, telephone networks, cellular telephone networks, fiber optic networks, local wireless networks (e.g., WiMAX, Bluetooth), satellite networks, and any other desired network, and each device of FIG. 1 may include the corresponding circuitry needed to communicate over the network 50, and to other devices on the network. Although the devices of the battery monitoring system 100 of FIG. 1 are illustrated as communicating over a common network 50, in some embodiments various point-to-point or device-to-device networks or communication links may be used in addition to or alternatively from the common network 50 for example to communicate data between a first device (e.g., the battery monitoring device 25) and a second device (e.g., the computing device 95).

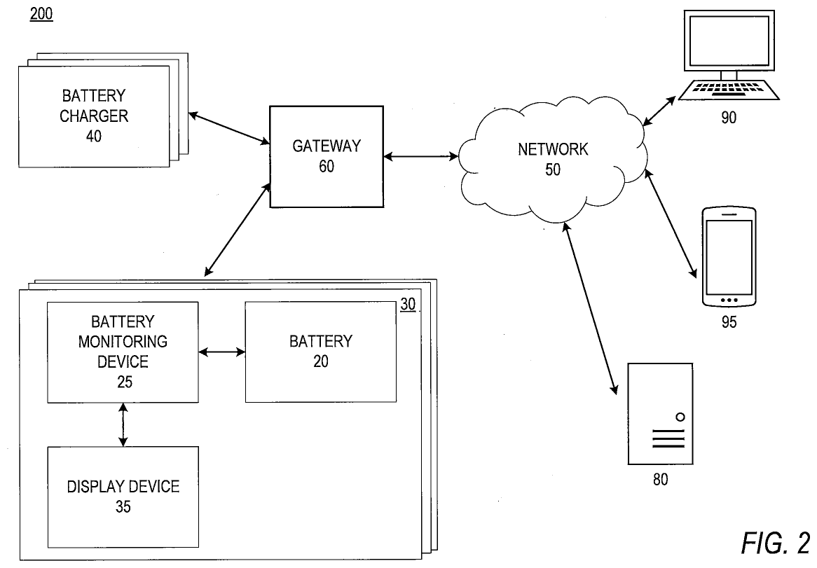

Furthermore, although each component of the illustrated battery monitory system 100 is shown as directly connected to the network 50 in FIG. 1, in some embodiments devices may be connected to one or more gateway devices that facilitates communications to the network 50 and remote devices. FIG. 2 shows an example system 200 in which multiple battery chargers 40 and multiple batteries 20 may communicate with a single gateway 60, which may be deployed, e.g., in a warehouse or other field/customer site. In some embodiments, multiple gateways 60 may be deployed. Deployment of a single gateway 60 or a group of multiple gateways 60 may permit technology agnostic communication, may prevent or reduce addressing of malicious or ill-formed data packets directly to batteries 20 or chargers 40, and may help in facilitating retrofitted deployments, given that field sites may have variable electrical and/or signal transmission characteristics.

Returning to the computing device 90, the computing device 90 may be configured to perform one or more methods to provide analytics of a battery 20 and/or of a charger 40 by utilizing a modeled “digital twin” of the battery 20 and/or the charger 40. For example, the computing device 90 may act as a cloud server, and may track the conditions of each battery 20 and/or each charger 40 present in the system 100 or 200 using a representative model of each battery 20 and each charger 40. Such representative models may be used to represent historical data of the battery (e.g., storing data indicative of a SOC of the battery 20 at historical points in time, storing data indicative of a temperature of the battery at historical points in time), and may be used to predict future values of properties of the battery (e.g., a remaining run time of the battery 20 at a point in time in the next N hours given a current load, a recharge time of the battery 20 at a point in time in the next P hours, based on an assumption that the battery 20 is connected to a charger 40 in the next X minutes).

Data may be ascertained based on the presence or absence of historical events. For example, it is desirable in some battery chemistries (e.g., lead acid) to perform an equalizing charge on the battery 20 as part of routine maintenance. Such a charge is intended to remove crystalline structures (e.g., sulfate crystals) that build up over time on the plates of the battery 20. Removing such structures increases the surface area of the plates that interacts with the electrolyte of the battery 20, and may provide both increased battery performance in the short term and/or an extension to the serviceable life of the battery 20 in the long term. As such, performing equalizing charges on a regular and routine basis (e.g., weekly, monthly, biannually, or at other periodic intervals according to the recommendations and/or specifications of the manufacturer) may extend a serviceable life of the battery 20, and failing to performing equalizing charges, or performing equalizing charges inconsistently may reduce a serviceable life of the battery 20. In some aspects, the digital twin data stored in the computing device 90 (and/or in the database 80) may be adjusted to reflect the performance of an equalizing charge, or lack of such performance. This data may be used in conjunction with other data to provide an estimate or to revise an estimate as to the serviceable life of the battery 20.

As discussed, there are numerous characteristics of a battery 20 that may be used in determining or analyzing the short- and long-term health and viability of the battery 20. Some characteristics include the presence or absence of a faulty cell in a multi-cell battery, the presence or absence of adequate electrolyte (particularly in user-serviceable batteries in which the electrolyte may be replaced from time to time), and/or the frequency and occurrence of overdischarging (that is, depleting a battery past a predetermined depth of discharge). Operating batteries in harsh conditions, such as beyond rated load (e.g., drawing too much current over a given time interval) or in conditions in which ambient and/or battery temperature is above a predetermined threshold may also affect the health and viability of the battery 20. In some aspects, data regarding characteristics of a battery 20 that may be difficult to measure directly may be instead determined based on other more easy to measure data that is then used in a model to derive the more-difficult-to-measure characteristic.

One or more of these characteristics may be used to analyze a battery 20 (and by extension each of the batteries present within a battery monitoring system 100 or 200) and the results of the analysis of the battery 20 may be used to provide a recommendation regarding the battery 20 and/or to perform one or more actions regarding the battery 20 autonomously (e.g., without user input).

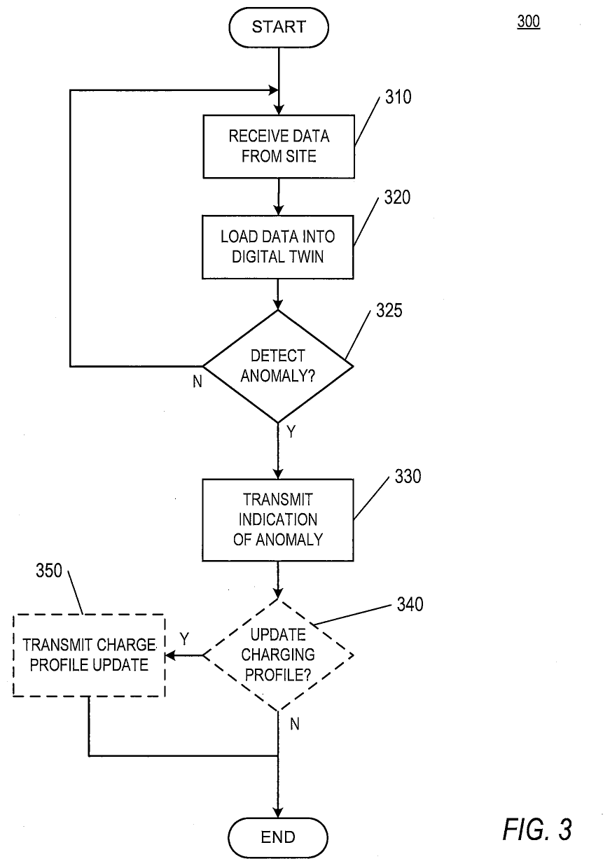

FIGS. 3-5 are flowcharts illustrating example methods of either providing recommendations regarding a battery 20 and/or performing one or more actions regarding the battery 20 autonomously. Although each method is shown in a separate Figure, such separation is only for convenience of explanation herein, and operations from each illustrated method may be combined into a single method or into other methods. In some aspects, the methods illustrated in FIGS. 3-5 and/or operations thereof may be executed serially or concurrently where appropriate. For example, operations 330 and 340/350 of FIG. 3 may be performed concurrently.

In FIG. 3, an example method 300 may include in a first operation 310 of receiving data from the field site. In some aspects, receiving data from the field site may include, e.g., receiving data from one or more batteries 20, one or more chargers 40, one or more battery monitoring devices 25, and/or one or more gateways 60. The data may be received via one or more computing devices (e.g., computing device 90, computing device 95, and/or database server 80). The data may be received via one or more networks 50. The data may be received by a device located relatively proximate to the field site, and/or may be received by a device located relatively remote from the field site. In some aspects, data values may be received in real-time (e.g., within several seconds after the data is captured at the field site). In some aspects, data may be received in a batch mode (e.g., where multiple data points are received in each transmission, with a transmission frequency being lower than a capture rate of the data).

In operation 320, data received from the field site may be loaded into a digital twin model. For example, when data received corresponds to a battery 20, said data may be stored in an model representation of the battery 20. When data is received from a charger 40, said data may be stored in a model representation of the charger 40 (if the data is associated with the charger 40) or in a model representation of the battery 20 (if the data is associated with the battery). Data received via one or more battery monitoring devices 25, and/or one or more gateways 60 may also be stored in a model representation of a device within the system 100 and/or 200.

In operation 325, the data stored in the model representations may be analyzed as to whether an anomaly is detected. For example, the data may be periodically analyzed (e.g., at successive repeating intervals). As another example, the data may be analyzed at a period of time subsequent to its receipt (e.g., responsive to receipt of the data in operation 310 and loading of the data in operation 320). In some aspects, detecting an anomaly may include determining that a data value exceeds a predetermined threshold, that a data value is below a predetermined threshold, that an event has occurred more frequently than expected, that an event has occurred less frequently than expected, that an event has occurred zero times, one time, or more than one time, and/or that data has not been received (e.g., ever, or for a period of time longer than a predetermined interval). Data values may include data received from the field site and/or data values calculated or estimated based on data values received from the field site. For example, a rate of change of a data value may be a separate data value calculated based on first and second data values received from the field site corresponding to conditions at first and second points in time. The rate of change may be calculated upon receipt of the second data value.

If no anomaly is detected (e.g., No branch from operation 325) than the method may return to operation 310 to await additional data. Once an anomaly is detected (e.g., Yes branch from operation 325), than in some aspects an indication of the detected anomaly may be transmitted. For example, the data may be transmitted from the one or more computing devices (e.g., computing device 90, computing device 95, and/or database server 80) to another of the one or more computing devices. The data may be transmitted via one or more networks 50. The data may be transmitted to a device located relatively proximate to the field site (e.g., at the field site), and/or may be transmitted to a device located relatively remote from the field site. The transmission may also include a recommendation, command, action, request, instruction, or other information to address the anomaly, although in some aspects this additional information may be transmitted separately.

As an example of a recommendation, command, action, request, instruction, or other information to address the anomaly, in some aspects the method 300 may include one or more operations to update the operation and/or functionality of one or more chargers 40 present at the field site. Accordingly, in operation 340 of method 300, it may be determined whether to update a charging profile of a charger 40. If so (e.g., Yes branch from operation 340), then a charge profile update may be transmitted to the charger 40 (via the network 50 and/or gateway 60) in operation 350. The charge profile may include characteristics such as setting a maximum amount of charge (in volts or as a percentage, e.g., depth of discharge), increasing or decreasing a voltage used to charge, increasing or decreasing a maximum charging temperature, and so on.

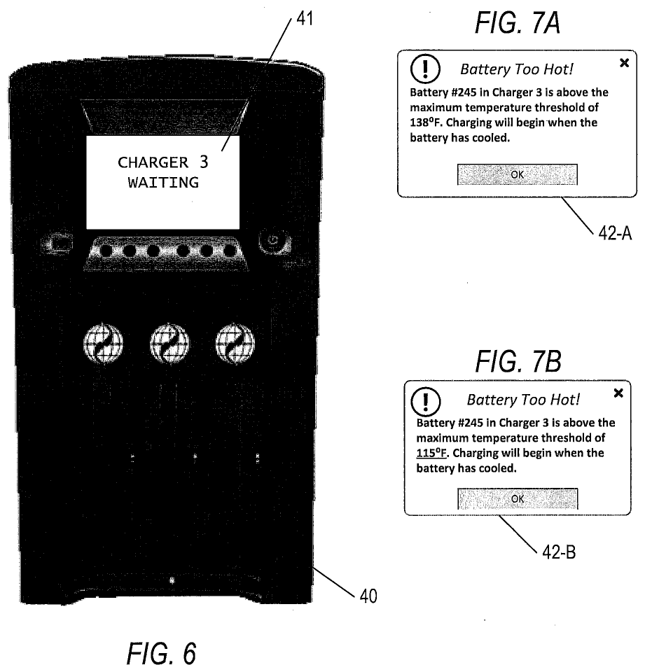

FIGS. 6 and 7A-B illustrate example aspects of what a user of a charging device 40 might experience before and after the updating of a charging profile (e.g., prior to and subsequent to performance of the method of FIG. 3). As seen in FIG. 6, a charger 40 may include a user interface that includes a screen or visual display apparatus 41. User input may be received via the user interface (for example, via the buttons or other user controls below the screen 41, via the screen 41 itself if the screen is a touchscreen, and so on), and may indicate information and/or status to the user via the screen and/or via other indicating devices (such as a speaker).

During operation of a battery 20 and while the battery 20 is connected to a load, the battery 20 may heat. Ambient temperature at the field site and/or poor or absent cooling techniques may cause the battery 20 to heat above a predetermined threshold. To prolong the life of a battery 20, and/or to safely charge the battery 20, the charger 40 may wait for the battery to cool and have a lower internal temperature than the predetermined threshold. In the example of FIGS. 6 and 7A-B ambient temperature within the field site and/or battery characteristics may result in batteries which are consistently above the predetermined threshold. In other words, a battery monitoring system 100 (and specifically computing devices thereof) may determine an increase in frequency in batteries 20 being connected to the charger 40 that are above a predetermined temperature threshold. FIG. 7A shows a visual display of the maximum temperature threshold of 138° F. in user interface element 42-A.

Although charging may begin once the battery 20 is below the maximum temperature threshold, the battery monitoring system 100 may determine that long-term harm (e.g., reduction in serviceable life of the battery 20) may result from continued initiation of charging at or near the maximum temperature threshold of 138° F. As such, the battery monitoring system 100 may transmit a command to the charger 40 (i.e., update the charging profile of the charger 40 and/or the battery 20) to reduce the maximum temperature threshold from a first threshold to a second threshold (e.g., 115° F.). This may result in the charger 40 waiting a longer period of time before initiating charging of the battery 20, with the longer period of time corresponding to the longer period of time for the battery to cool to reach the second threshold as compared to the first threshold. FIG. 7B shows a visual display of the second temperature threshold of 115° F. in user interface element 42-B. In some aspects, an expected time to recharge may be visually indicated in the user interface element 42-A or 42-B, taking into account the period of time that the charger 40 will wait before initiating charging of the battery 20.

Although the example given in FIG. 3 is to update the charge profile, in some aspects a battery discharge profile may also be updated or be updated instead of the charge profile. As is known in the art, batteries may be manufactured or internally managed to communicate that they are at a state of complete discharge even while some charge remains in the battery. Discharging beyond this point may result in damage to either the battery and/or to the load. Thus, aspects of the present disclosure provide that a battery discharge profile may be updated to set a discharge threshold higher or lower than previously set. Thus, the battery may indicate that it is “fully” discharged at a greater or lower depth of discharge than previously.

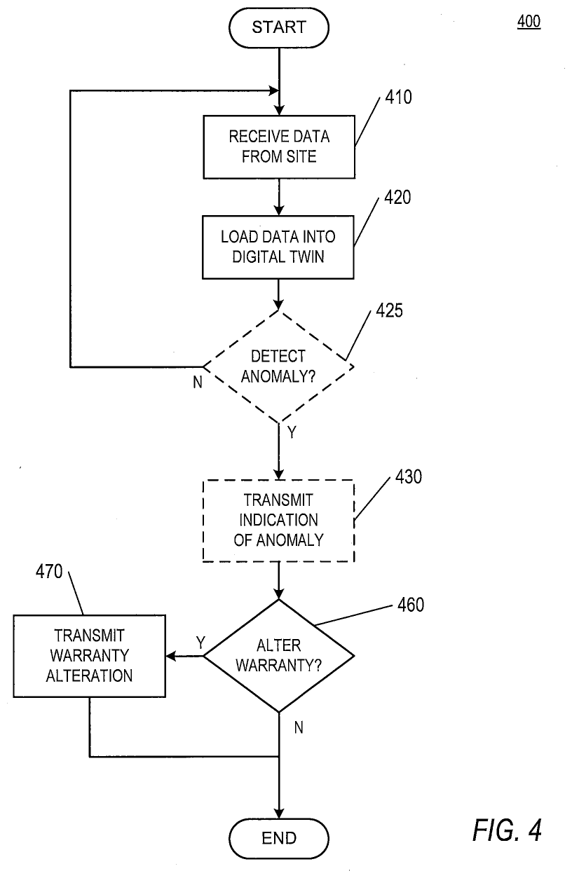

FIG. 4 provides a method 400 showing additional operations that may be performed within a battery monitoring system. Operations 410 and 420 are similar to those discussed above with respect to FIG. 3 and operations 310 and 320 therein, and optional operations 425 and 430 are similar to those discussed above with respect to FIG. 3 and operations 325 and 330 therein. In operation 460, it may be determined whether to update a warranty of a battery asset 20. If so (e.g., Yes branch from operation 460), then a warranty alteration may be transmitted in operation 470.

Underlying FIG. 4 is an understanding that batteries, like other manufactured articles for businesses, may have warranties thereon to ensure to the purchaser or operator that the battery is suitable for its intended purpose for a given length of time. Defects in the manufacturing or design of a battery may result in its premature failure, and as such the manufacturer may repair or replace the battery at either no cost to the purchaser or at a cost lower than the replacement cost for the battery. Such warranties are typically predicated on the idea that they cover certain conditions and account for normal usage or operation of the battery and that the battery is maintained routinely and per the manufacturer's instructions.

The battery monitoring systems of the present disclosure provide insight into how batteries are used by a purchaser at a field site, and thus present the capability of providing more dynamic warranties that reflect the proper or improper usage of a battery. For example, a user that properly maintains a battery asset and uses it in light conditions (e.g., does not overload the battery, does not overdischarge the battery) may prolong the life of the battery asset 20 to the point that the manufacturer is willing or able to cover a greater period of warranty term. Conversely, a user that does not properly maintain the battery and/or exceeds the rated specifications of the battery on a routine basis may shorten the life of the battery asset, and the manufacturer may not be willing or able to cover a greater period of warranty term (or may indicate that further instances of battery mismanagement may result in termination of a warranty). Alterations to a warranty or to the warranties of a battery may be thus managed more dynamically via the method 400 of FIG. 4.

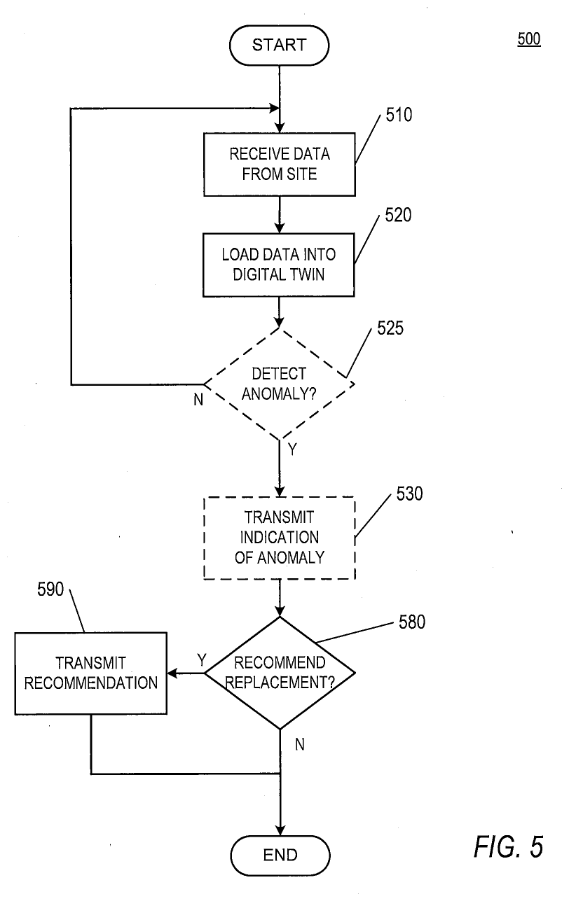

FIG. 5 provides a method 500 showing additional operations that may be performed within a battery monitoring system. Operations 510 and 520 are similar to those discussed above with respect to FIG. 3 and operations 310 and 320 therein, and optional operations 525 and 530 are similar to those discussed above with respect to FIG. 3 and operations 325 and 330 therein. In operation 580, it may be determined whether to recommend replacement of a battery asset 20. If so (e.g., Yes branch from operation 460), then a warranty alteration may be transmitted in operation 590.

Underlying FIG. 5 is an understanding that batteries may require replacement from time to time to ensure continued support of the operations at a field site. Prediction of a need to replace a battery prior to its failure provides to the user an ability to reduce downtime resulting from a battery failure, and provide a manufacturer the capability of providing improved customer service.

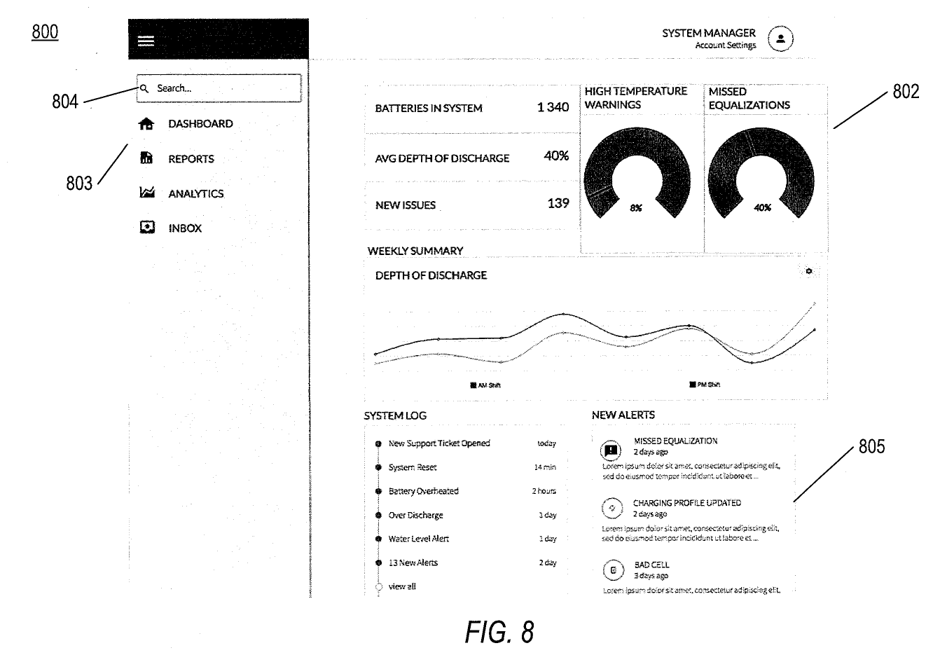

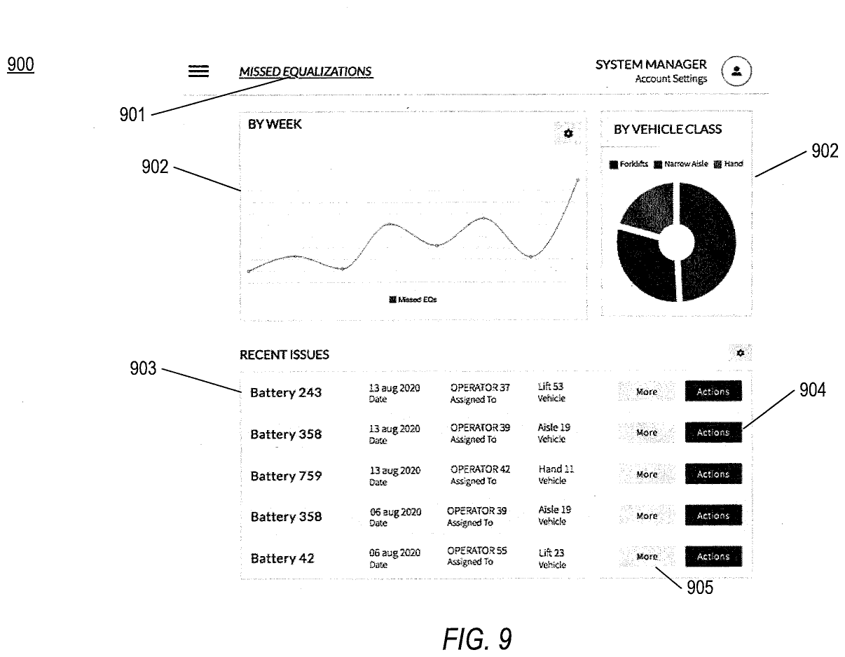

FIG. 8 and FIG. 9 illustrate various aspects of an example user interface that can be used in conjunction with the battery monitoring systems discussed herein. As seen in FIG. 8, a “dashboard” view 800 may be provided in which collected characteristics and historical data of the battery assets within a given field operation (e.g., warehouse) are summarized and presented visually, graphically, and/or tabularly. In some aspects, one or more visual display areas within a graphical user interface (GUI) may be customizable and may present a particular data set of interest to a user, and the battery monitoring system may store such customizations as a user preference. For example, instead of a view showing data indicating missed equalizations (e.g., equalizations that were scheduled during a given time interval but were not performed) in display area 802, a user may express a preference to instead show visual display of data showing a percentage of battery assets having low electrolyte levels. A user may be able to search for one or more specific battery assets, users, alerts, chargers, reports, data sets, or other stored data objects using search field 804. For example, a user may input a search requesting all battery assets that have had a missed equalization in the past six months; a user may execute a previously input search for a specific battery asset, or a group of battery assets (e.g., all lead-acid batteries), or may request details regarding all adverse events that have occurred in the past six months or that are predicted to occur in the next seven days (again, as examples). Other performable tasks or operations may be provided to a user in area 803. In some aspects, permissions may be used to allow or disallow a user from accessing a report or set of reports. In some aspects, alerts as discussed above may be communicated to one or more users and displayed in e.g., display area 805.

As seen in FIG. 9, a more-specific “drill-down” view 900 may result from execution or retrieval of one or more searches performed by the battery monitoring system, or may result from other user input. For example, the user may select a chart in display area 802 and may be redirected to a drill-down view providing greater detail regarding the data indicated by the chart in the display area. For example, if a user selects a missed equalization chart, more information may be displayed graphically in display area 902 and/or tabularly in area 903, with different information present in these areas in some embodiments. Greater additional detail may be provided on an asset-specific view selectable using user interface element 905. For example, details regarding a specific battery asset (e.g., “Battery 42”) may be shown by clicking the “More” button at element 905, which may show any or all of the characteristics discussed herein as well as other battery characteristics. In some aspects, a user may be permitted to perform one or more actions via user interface elements 904. For example, a managing user may select an action which transmits a notification to one or more users that a specific battery needs to be submitted for maintenance, or may transmit a notification to a charger or group of chargers that the next time the specific battery is connected to the charger or to a charger in the group that a user notification is displayed on a screen of the charger that the battery requires maintenance. As another example, the user may indicate via the user interface elements 904 that the battery monitoring system is commanded schedule the battery for an equalizing charge instead of a non-equalizing charge, and to reassign other battery assets to account for the scheduled equalizing charge, and so on.

The discussion herein of examples related to battery equalizations are provided only as examples, and it is envisioned that within the scope of the present disclosure are many other scenarios in which data is collected by the battery monitoring system and analyzed to determine one or more operations that may be performed responsive to indications in the data, and then autonomously performing the one or more operations or recommending the performance of such operations.

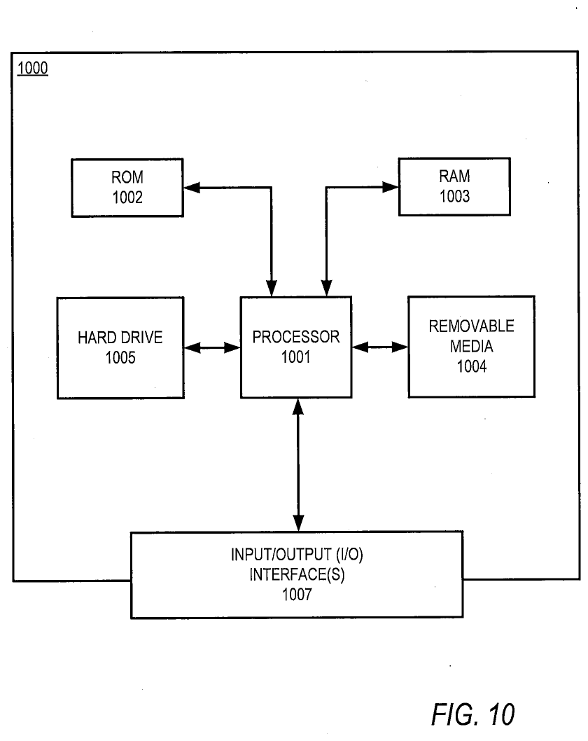

FIG. 10 illustrates various components of a computing device 1000 which may be used to implement one or more of the devices herein, including the battery monitoring device 25, the charger 40, the database 80, and/or the computing devices 90, 95 of FIG. 1. FIG. 10 illustrates hardware elements that can be used in implementing any of the various computing devices discussed herein. In some aspects, general hardware elements may be used to implement the various devices discussed herein, and those general hardware elements may be specially programmed with instructions that execute the algorithms discussed herein. In special aspects, hardware of a special and non-general design may be employed (e.g., ASIC or the like). Various algorithms and components provided herein may be implemented in hardware, software, firmware, or a combination of the same.

A computing device 1000 may include one or more processors 1001, which may execute instructions of a computer program to perform any of the features described herein. The instructions may be stored in any type of computer-readable medium or memory, to configure the operation of the processor 1001. For example, instructions may be stored in a read-only memory (ROM) 1002, random access memory (RAM) 1003, removable media 1004, such as a Universal Serial Bus (USB) drive, compact disk (CD) or digital versatile disk (DVD), floppy disk drive, or any other desired electronic storage medium. Instructions may also be stored in an attached (or internal) hard drive 1005. The computing device 1000 may be configured to provide output to one or more output devices (not shown) such as printers, monitors, display devices, and so on, and receive inputs, including user inputs, via input devices (not shown), such as a remote control, keyboard, mouse, touch screen, microphone, or the like. The computing device 1000 may also include input/output interfaces 1007 which may include circuits and/or devices configured to enable the computing device 1000 to communicate with external input and/or output devices (e.g., the battery 20, devices coupled to the network 50) on a unidirectional or bidirectional basis. The components illustrated in FIG. 10 (e.g., processor 1001, ROM storage 1002) may be implemented using basic computing devices and components, and the same or similar basic components may be used to implement any of the other computing devices and components described herein. For example, the various components herein may be implemented using computing devices having components such as a processor executing computer-executable instructions stored on a computer-readable medium, as illustrated in FIG. 10.

The various inventive concepts described herein provide several distinctive advantages. First, the inventive concepts provided herein provide comprehensive algorithms for analyzing, predicting, and measuring expected battery life and/or other characteristics of a battery. These predicted and measured characteristics of a battery may be used to, e.g., extend or reduce a warranty period in which repair or replacement of the battery is provided, or may be used to alter a charging profile of the battery to extend a serviceable life of the battery. The inventors have recognized that prior systems did not provide such comprehensiveness.

Second, the present inventive concepts provide a communication system in which a battery charger, a battery and/or battery monitoring device, and one or more remote computer devices may communicate data, commands, alerts, recommendations, and other information. This information provides an improvement not only to the individual devices therein (for example, by extending battery serviceable life), but also provides improved reliability and/or uptime to the field operation in which the batteries are used (such as warehouse management, supply chain management, and so on).

Third, the inventive concepts herein improve the prediction accuracy of maintenance within the system, reducing the reliance on fixed schedules for certain maintenance tasks. Relatedly, the inventive concepts herein may be used in automation, prediction, and promotion of service calls, increasing the efficiency of the service organization.

The inventive concepts provided by the present disclosure have been be described above with reference to the accompanying drawings and examples, in which examples of embodiments of the inventive concepts are shown. The inventive concepts provided herein may be embodied in many different forms than those explicitly disclosed herein, and the present disclosure should not be construed as limited to the embodiments set forth herein. Rather, the examples of embodiments disclosed herein are provided so that this disclosure will be thorough and complete, and will fully convey the scope of the inventive concepts to those skilled in the art. Like numbers refer to like elements throughout.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the specification and relevant art and should not be interpreted in an idealized or overly formal sense unless expressly so defined herein. Well-known functions or constructions may not be described in detail for brevity and/or clarity.

Some of the inventive concepts are described herein with reference to block diagrams and/or flowchart illustrations of methods, apparatus (systems) and/or computer program products, according to embodiments of the inventive concepts. It is understood that one or more blocks of the block diagrams and/or flowchart illustrations, and combinations of blocks in the block diagrams and/or flowchart illustrations, can be implemented by computer program instructions. These computer program instructions may be provided to a processor of a general purpose computer, special purpose computer, and/or other programmable data processing apparatus to produce a machine, such that the instructions, which execute via the processor of the computer and/or other programmable data processing apparatus, create means for implementing the functions/acts specified in the block diagrams and/or flowchart block or blocks.

These computer program instructions may also be stored in a computer-readable memory that can direct a computer or other programmable data processing apparatus to function in a particular manner, such that the instructions stored in the computer-readable memory produce an article of manufacture including instructions which implement the function/act specified in the block diagrams and/or flowchart block or blocks.

The computer program instructions may also be loaded onto a computer or other programmable data processing apparatus to cause a series of operational steps to be performed on the computer or other programmable apparatus to produce a computer-implemented process such that the instructions which execute on the computer or other programmable apparatus provide steps for implementing the functions/acts specified in the block diagrams and/or flowchart block or blocks.

Accordingly, the inventive concepts may be embodied in hardware and/or in software (including firmware, resident software, micro-code, etc.). Furthermore, embodiments of the present inventive concepts may take the form of a computer program product on a computer-usable or computer-readable non-transient storage medium having computer-usable or computer-readable program code embodied in the medium for use by or in connection with an instruction execution system.

The computer-usable or computer-readable medium may be, for example but not limited to, an electronic, optical, electromagnetic, infrared, or semiconductor system, apparatus, or device. More specific examples (a non-exhaustive list) of the computer-readable medium would include the following: an electrical connection having one or more wires, a portable computer diskette, a random access memory (RAM), a read-only memory (ROM), an erasable programmable read-only memory (EPROM or Flash memory such as an SD card), an optical fiber, and a portable compact disc read-only memory (CD-ROM).

The terms first, second, etc. may be used herein to describe various elements, but these elements should not be limited by these terms. These terms are only used to distinguish one element from another. For example, a first element could be termed a second element, and, similarly, a second element could be termed a first element, without departing from the scope of the present inventive concepts. As used herein, the term “and/or” includes any and all combinations of one or more of the associated listed items. As used herein, the singular forms “a”, “an” and “the” are intended to include the plural forms as well, unless the context clearly indicates otherwise. It should be further understood that the terms “comprises,” “comprising,” “includes,” and/or “including” when used herein, specify the presence of stated features, operations, elements, and/or components, but do not preclude the presence or addition of one or more other features, operations, elements, components, and/or groups thereof.

When an element is referred to as being “on” another element, it can be directly on the other element or intervening elements may also be present. In contrast, when an element is referred to as being “directly on” another element, there are no intervening elements present. When an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (i.e., “between” versus “directly between”, “adjacent” versus “directly adjacent”, etc.).

The terminology used herein is for the purpose of describing particular embodiments only and is not intended to be limiting of the present disclosure.

Aspects and elements of all of the embodiments disclosed above can be combined in any way and/or combination with aspects or elements of other embodiments to provide a plurality of additional embodiments. Although a few exemplary embodiments of the inventive concepts have been described, those skilled in the art will readily appreciate that many modifications are possible in the exemplary embodiments without materially departing from the novel teachings and advantages of the inventive concepts provided herein. Accordingly, all such modifications are intended to be included within the scope of the present application as defined in the claims.

What is claimed is:

1. A method comprising:
measuring one or more properties of a battery by a device communicatively coupled to the battery;
transmitting the measured one or more properties to a computing device located remotely from the battery;
detecting, by the computing device and based on the measured one or more properties, one or more anomalous conditions within the battery; and
transmitting, by the computing device, an indication of the one or more anomalous conditions.

2. The method of claim 1, wherein the measured one or more properties comprises a current flow to or from the battery.

3. The method of claim 1, wherein the measured one or more properties comprises a temperature of the battery.

4. The method of claim 1, further comprising:
transmitting, by the computing device, one or more updates to a charger configured to charge the battery, wherein the one or more updates are configured to change an operation of the charger during charging of the battery to address the one or more anomalous conditions within the battery.

5. The method of claim 4, wherein the measured one or more properties comprise a temperature of the battery, wherein the one or more anomalous conditions within the battery comprise the battery being above a predetermined threshold, and wherein the one or more updates transmitted to the charger are configured to reduce a maximum charging temperature of the battery from a first value to a second value lower than the first value.

6. The method of claim 1, further comprising generating, by the computing device, one or more predictions of properties of the battery.

7. The method of claim 6, further comprising:
performing one or more actions based on the generated one or more predictions of the properties of the battery.

8. The method of claim 7, wherein the performed one or more actions comprises transmitting the one or more predictions to a display device.

9. The method of claim 7, wherein the performed one or more actions comprises altering a term of a warranty covering the battery.

10. The method of claim 7, wherein the performed one or more actions comprises transmitting a recommendation to purchase a replacement of the battery.

11. The method of claim 1, wherein transmitting the measured one or more properties to the computing device located remotely from the battery comprises transmitting the measured one or more properties via a gateway.

12. An apparatus comprising:
a processor; and
memory storing computer-readable instructions that, when executed by the processor, cause the processor to perform operations comprising:
receiving one or more measured properties of a battery from a device communicatively coupled to the battery;
detecting, based on the one or more measured properties, one or more anomalous conditions within the battery; and
transmitting an indication of the one or more anomalous conditions.

13. The apparatus of claim 12, wherein the apparatus is remotely located from the device communicatively coupled to the battery.

14. The apparatus of claim 12, wherein the memory stores further computer-readable instructions that, when executed by the processor, cause the processor to perform further operations comprising:
transmitting one or more updates to a charger configured to charge the battery, wherein the one or more updates are configured to change an operation of the charger during charging of the battery to address the one or more anomalous conditions within the battery.

15. The apparatus of claim 14, wherein the measured one or more properties comprise a temperature of the battery, wherein the one or more anomalous conditions within the battery comprise the battery being above a predetermined threshold, and wherein the one or more updates transmitted to the charger are configured to reduce a maximum charging temperature of the battery from a first value to a second value lower than the first value.

16. The apparatus of claim 12, wherein the one or more measured properties are received via a gateway.

17. A battery monitoring system, comprising:
a battery;
a battery monitoring apparatus communicatively coupled to the battery; and
a computing device communicatively coupled to the battery monitoring apparatus;
wherein the computing device is configured to perform operations comprising:
receiving one or more measurements of characteristics of the battery;
determining one or more anomalous properties of the battery; and
transmitting one or more updates to a charger configured to charge the battery, wherein the one or more updates are configured to change an operation of the charger during charging of the battery to address the one or more anomalous properties of the battery.

18. The system of claim 17, wherein the one or more measurements of the battery comprise a measured temperature of the battery, wherein the one or more anomalous properties of the battery comprise the battery being above a predetermined threshold, and wherein the one or more updates transmitted to the charger are configured to reduce a maximum charging temperature from a first value to a second value lower than the first value.

19. The system of claim 17, wherein the one or more measurements of the battery comprise a time since a equalization charge of the battery was performed, wherein the one or more anomalous properties of the battery comprise the time since an equalization charge of the battery was performed exceeding a predetermined threshold, and wherein the one or more updates transmitted to the charger are configured to initiate an equalization charge of the battery in lieu of a non-equalization charge.

20. The system of claim 17, further comprising at least one remote device located remotely from the battery monitoring apparatus and from the computing device, wherein the computing device is configured to transmit one or more predictions of characteristics of the battery via a network.
